(19) United States
(12) Patent Application Publication
(10) Pub. No.: US 2024/0194781 A1
(43) Pub. Date: Jun. 13, 2024

(54) SILICON CARBIDE SEMICONDUCTOR DEVICE

(71) Applicant: FUJI ELECTRIC CO., LTD., Kawasaki-shi (JP)

(72) Inventor: Naoyuki OHSE, Matsumoto-city (JP)

(73) Assignee: FUJI ELECTRIC CO., LTD., Kawasaki-shi (JP)

(21) Appl. No.: 18/492,118

(22) Filed: Oct. 23, 2023

(30) Foreign Application Priority Data
Dec. 8, 2022 (JP) 2022-196318

(51) Int. Cl. H01L 29/78; H01L 29/08; H01L 29/16; H01L 29/417

(52) U.S. Cl. CPC H01L 29/7813; H01L 29/0865; H01L 29/1608; H01L 29/41741

(57) ABSTRACT

A silicon carbide semiconductor device includes: a drift layer of a first conductivity-type, a base region of a second conductivity-type, and a main region of the first conductivity-type each including silicon carbide; a gate insulating film and a gate electrode buried inside a trench penetrating the main region and the base region; and a main electrode provided in contact with the main region, wherein the main region includes a source expansion part with a bottom surface in contact with the base region, and a source contact part having a 3C structure provided on a top surface side of the source expansion part so as to be in contact with the main electrode, and a top surface of the gate electrode is deeper than a bottom surface of the source contact part and is shallower than a bottom surface of the source expansion part.

### CROSS-REFERENCE TO RELATED APPLICATION

This application claims benefit of priority under 35 USC 119 based on Japanese Patent Application No. 2022-196318 filed on Dec. 8, 2022, the entire contents of which are incorporated by reference herein.

### BACKGROUND OF THE INVENTION

### 1. Field of the Invention

The present invention relates to a silicon carbide (SiC) semiconductor device including SiC.

### 2. Description of the Related Art

JP 2009-049198 A discloses a semiconductor device including an amorphous layer obtained by implanting impurity ions of phosphorus into a hexagonal single crystal silicon carbide substrate, and an electrode obtained by subjecting the amorphous layer to annealing to be recrystallized into n-type silicon carbide of cubic single crystals so as to vapor-deposit nickel on the top surface of the n-type silicon carbide.

WO 2017/042963 A1 discloses a semiconductor device including an n⁻ type epitaxially-grown layer grown on a first main surface of an n⁺-type SiC substrate including 4H—SiC, an n⁺-type source region formed in the n⁻ type epitaxially-grown layer, and an n⁺-type 3C—SiC region and a p⁺-type potential fixing region each formed in the n⁺-type source region, in which a barrier metal film is formed in contact with the n⁺-type 3C—SiC region and the p⁺-type potential fixing region, and a source wiring electrode is further formed on the barrier metal film.

JP 5369464 B2 discloses a silicon carbide MOS semiconductor device including a body contact region of a second conductivity-type and a source contact region of a first conductivity-type each formed by selective ion implantation on a surface layer of a body region of the second conductivity-type, and a source expansion region formed by selective ion implantation in a part deeper than a tail part located under the source contact region and having a lower impurity concentration than the source contact region.

A study of trench-gate SiC semiconductor devices has been promoted that have a configuration in which a source region (a main region) includes 3C—SiC so as to be in ohmic contact with a source electrode (a main electrode). However, since 3C—SiC has greater crystal defects than 4H—SiC and tends to cause a roughened surface, the case of including 3C—SiC has a problem of a leak current that would flow between the gate electrode and the source region.

### SUMMARY OF THE INVENTION

In view of the foregoing problems, the present invention provides a trench-gate SiC semiconductor device having a configuration capable of leading a main region to be in ohmic contact with a main electrode, and avoiding a leak current between a gate electrode and the main region.

An aspect of the present invention inheres in a silicon carbide semiconductor device including: a drift layer of a first conductivity-type including silicon carbide; a base region of a second conductivity-type including silicon carbide provided on a top surface side of the drift layer; a main region of the first conductivity-type including silicon carbide provided on a top surface side of the base region; a gate insulating film provided inside a trench penetrating the main region and the base region; a gate electrode buried inside the trench with the gate insulating film interposed; and a main electrode provided in contact with the main region, wherein the main region includes a source expansion part with a bottom surface in contact with the base region, and a source contact part having a 3C structure provided on a top surface side of the source expansion part so as to be in contact with the main electrode, and a top surface of the gate electrode at a position in contact with the gate insulating film is deeper than a bottom surface of the source contact part and is shallower than a bottom surface of the source expansion part.

### BRIEF DESCRIPTION OF THE DRAWINGS

FIG. 1 is a schematic cross-sectional view illustrating an example of a SiC semiconductor device according to a first embodiment;

FIG. 2 is an enlarged schematic cross-sectional view of region A in FIG. 1;

FIG. 3 is a schematic cross-sectional view illustrating a SiC semiconductor device of a comparative example;

FIG. 4 is a flowchart of a method of manufacturing the SiC semiconductor device according to the first embodiment;

FIG. 5 is a schematic cross-sectional view for explaining an example of the method of manufacturing the SiC semiconductor device according to the first embodiment;

FIG. 6 is a schematic cross-sectional view continued from FIG. 5, for explaining the example of the method of manufacturing the SiC semiconductor device according to the first embodiment;

FIG. 7 is a schematic cross-sectional view continued from FIG. 6, for explaining the example of the method of manufacturing the SiC semiconductor device according to the first embodiment;

FIG. 8 is a schematic cross-sectional view continued from FIG. 7, for explaining the example of the method of manufacturing the SiC semiconductor device according to the first embodiment;

FIG. 9 is a schematic cross-sectional view continued from FIG. 8, for explaining the example of the method of manufacturing the SiC semiconductor device according to the first embodiment t;

FIG. 10 is a schematic cross-sectional view continued from FIG. 9, for explaining the example of the method of manufacturing the SiC semiconductor device according to the first embodiment;

FIG. 11 is a schematic cross-sectional view continued from FIG. 10, for explaining the example of the method of manufacturing the SiC semiconductor device according to the first embodiment;

FIG. 12 is a schematic cross-sectional view continued from FIG. 11, for explaining the example of the method of manufacturing the SiC semiconductor device according to the first embodiment;

FIG. 13 is a schematic cross-sectional view continued from FIG. 12, for explaining the example of the method of manufacturing the SiC semiconductor device according to the first embodiment;

FIG. 14 is a schematic cross-sectional view continued from FIG. 13, for explaining the example of the method of manufacturing the SiC semiconductor device according to the first embodiment;

FIG. 15 is a schematic cross-sectional view continued from FIG. 14, for explaining the example of the method of manufacturing the SiC semiconductor device according to the first embodiment;

FIG. 16 is a flowchart of a method of manufacturing a SiC semiconductor device according to a second embodiment; and

FIG. 17 is a flowchart of a method of manufacturing a SiC semiconductor device according to a third embodiment.

### DETAILED DESCRIPTION

With reference to the drawings, first to third embodiments of the present invention will be described below.

In the drawings, the same or similar elements are indicated by the same or similar reference numerals, and overlapping explanations are not repeated. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions.

The first to third embodiments described below merely illustrate schematically devices and methods for specifying and giving shapes to the technical idea of the present invention, and the span of the technical idea is not limited to materials, shapes, structures, and relative positions of elements described herein.

As used in the present specification, a source region of a metal-oxide-semiconductor field-effect transistor (MOSFET) is referred to as “one of the main regions (a first main region)” that can be used as an emitter region of an insulated gate bipolar transistor (IGBT). The “one of the main regions”, when provided in a thyristor such as a MOS controlled static induction thyristor (SI thyristor), can be used as a cathode region. A drain region of the MOS transistor is referred to as the “other one of the main regions (a second main region)” of the semiconductor device that can be used as a collector region in the IGBT or as an anode region in the thyristor. The term “main region”, when simply mentioned in the present specification, is referred to as either the first main region or the second main region that is determined as appropriate by the person skilled in the art.

Further, definitions of directions such as an up-and-down direction in the following description are merely definitions for convenience of understanding, and are not intended to limit the technical ideas of the present invention. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction. In addition, an “upper surface” may be read as “front surface”, and a “lower surface” may be read as “back surface”.

Further, in the following description, there is exemplified a case where a first conductivity-type is an n-type and a second conductivity-type is a p-type. However, the relationship of the conductivity types may be inverted to set the first conductivity-type to the p-type and the second conductivity-type to the n-type. Further, a semiconductor region denoted by the symbol “n” or “p” attached with “+” indicates that such semiconductor region has a relatively high impurity concentration or a relatively low specific resistance as compared to a semiconductor region denoted by the symbol “n” or “p” without “+”. A semiconductor region denoted by the symbol “n” or “p” attached with “−” indicates that such semiconductor region has a relatively low impurity concentration or a relatively high specific resistance as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration or the same specific resistance.

In addition, a crystal polymorphism is present in SiC crystals, and main examples include 3C of a cubic crystal, and 4H and 6H of a hexagonal crystal. A bandgap at room temperature is reported that is 2.23 eV in 3C—SiC, 3.26 eV in 4H—SiC, and 3.02 eV in 6H—SiC. The following embodiments are illustrated with a case of mainly using 4H—SiC and 3C—SiC.

### First Embodiment

### <Structure of SiC Semiconductor Device>

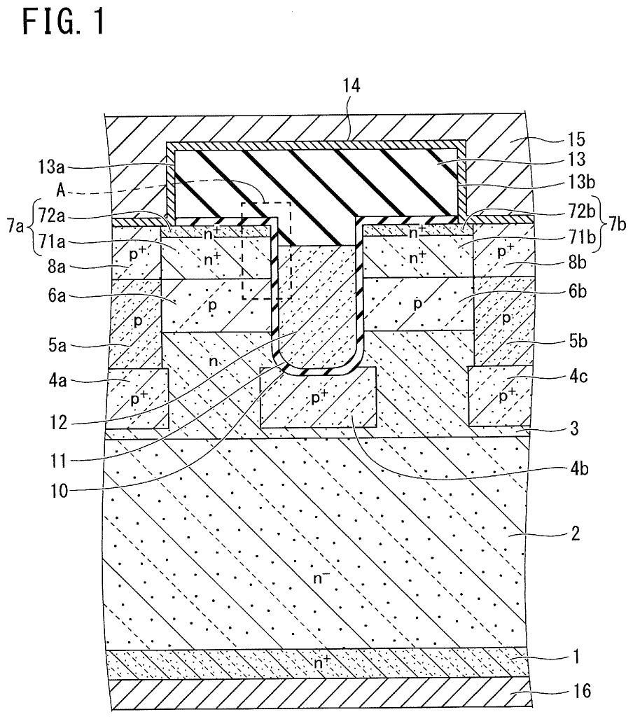

A SiC semiconductor device according to a first embodiment is illustrated below with a case of including a trench-gate MOSFET as an active element, as illustrated in FIG. 1. While FIG. 1 illustrates a unit cell including an insulated gate electrode structure (11, 12) buried in a single trench 10, the plural unit cells are actually arranged repeatedly.

The SiC semiconductor device according to the first embodiment includes a drift layer 2 of a first conductivity-type (nt-type). The drift layer 2 is an epitaxially-grown layer including SiC such as 4H—SiC, for example. The drift layer 2 has an impurity concentration in a range of about 1×10¹⁵ cm⁻³ or greater and 5×10¹⁶ cm⁻³ or less, for example. The drift layer 2 has a thickness in a range of about 1 micrometer or greater and 100 micrometers or smaller, for example. The impurity concentration and the thickness of the drift layer 2 can be adjusted as appropriate depending on the breakdown voltage specifications, for example.

A current spreading layer (CSL) 3 of a first conductivity-type (n-type) having a higher impurity concentration than the drift layer 2 is selectively deposited on the top surface side of the drift layer 2. The bottom surface of the current spreading layer 3 is in contact with the top surface of the drift layer 2. The current spreading layer 3 is an epitaxially-grown layer including SiC such as 4H—SiC, for example. The current spreading layer 3 has an impurity concentration in a range of about 5×10¹⁶ cm⁻³ or greater and 5×10¹⁷ cm⁻³ or less, for example. The SiC semiconductor device does not necessarily include the current spreading layer 3, and the drift layer 2 may be arranged to extend toward a region corresponding to the current spreading layer 3 when not provided.

Base regions 6a and 6b of a second conductivity-type (p-type) is deposited on the top surface side of the current spreading layer 3. The respective bottom surfaces of the base regions 6a and 6b are in contact with the top surface of the current spreading layer 3. The respective bottom surfaces of the base regions 6a and 6b are in contact with the top surface of the drift layer 2 when the current spreading layer 3 is not provided. The base regions 6a and 6b are each an epitaxially-grown layer including SiC such as 4H—SiC. The base regions 6a and 6b may each be a region obtained such that p-type impurity ions are implanted into the current spreading layer 3. The respective base regions 6a and 6b have an impurity concentration in a range of about 1×10¹⁶ cm⁻³ or greater and 1×10¹⁸ cm⁻³ or less.

First main regions (source regions) 7a and 7b of the first conductivity-type (n⁺-type) having a higher impurity concentration than the drift layer 2 are selectively deposited on the top surface side of the base regions 6a and 6b. The source regions 7a and 7b are each a region including SiC obtained such that n-type impurity ions are implanted into the base regions 6a and 6b, for example.

The source region 7a has a two-layer structure including a source expansion part 71a of n⁺-type as a lower layer and a source contact part 72a of n⁺-type as an upper layer. The bottom surface of the source expansion part 71a is in contact with the top surface of the base region 6a. The top surface of the source expansion part 71a is in contact with the bottom surface of the source contact part 72a. The source region 7b has a two-layer structure including a source expansion part 71b of n⁺-type as a lower layer and a source contact part 72b of n⁺-type as an upper layer. The bottom surface of the source expansion part 71b is in contact with the top surface of the base region 6b. The top surface of the source expansion part 71b is in contact with the bottom surface of the source contact part 72b.

The trench 10 is provided to penetrate the respective source regions 7a and 7b and the respective base regions 6a and 6b from the top surfaces of the source regions 7a and 7b in the normal direction with respect to the top surface of the respective source regions 7a and 7b (in the depth direction). The bottom surface of the trench 10 reaches the current spreading layer 3. The trench 10 has a width of about one micrometer or smaller, for example. The source region 7a and the base region 6a are in contact with the side surface of the trench 10 on the left side. The source region 7b and the base region 6b are in contact with the side surface of the trench 10 on the right side. The trench 10 may have a planar pattern extending in a stripe state in the backside direction and the front direction in the sheet of FIG. 1, or may have a dot-like planar pattern.

A gate insulating film 11 is provided along the bottom surface and the side surfaces on both sides of the trench 10. A gate electrode 12 is buried inside the trench 10 with the gate insulating film 11 interposed. The gate insulating film 11 and the gate electrode 12 implement a trench-gate insulated gate electrode structure (11, 12).

The gate insulating film 11 as used herein can be a silicon oxide film (a SiO₂ film), or a single film of a silicon oxynitride (SiON) film, a strontium oxide (SrO) film, a silicon nitride (Si₃N₄) film, an aluminum oxide (Al₂O₃) film, a magnesium oxide (MgO) film, an yttrium oxide (Y₂O₃) film, a hafnium oxide (HfO₂) film, a zirconium oxide (ZrO₂) film, a tantalum oxide (Ta₂O₅) film, or a bismuth oxide (Bi₂O₃) film, or a composite film including some of the above films stacked on one another. The gate electrode 12 can be made of a polysilicon layer (a doped polysilicon layer) heavily doped with p-type or n-type impurity ions or made of a layer including refractory metal such as titanium (Ti), tungsten (W), or nickel (Ni), for example.

A gate bottom protection region 4b of the second conductivity-type (p⁺-type) is provided at the bottom of the trench 10 inside the current spreading layer 3. The top surface of the gate bottom protection region 4b is in contact with the bottom surface of the trench 10. The top surface of the gate bottom protection region 4b is not necessarily in contact with the bottom surface of the trench 10. The gate bottom protection region 4b has an impurity concentration in a range of about 1×10¹⁷ cm⁻³ or greater and 1×10¹⁹ cm⁻³ or less, for example.

First buried regions 4a and 4c of the second conductivity-type (p⁺-type) are provided inside the current spreading layer 3 separately from the gate bottom protection region 4b. The first buried regions 4a and 4c are located at substantially the same depth as the gate bottom protection region 4b. The respective first buried regions 4a and 4c have an impurity concentration in a range of about 1×10¹⁷ cm⁻³ or greater and 1×10¹⁹ cm⁻³ or less, for example. The first buried regions 4a and 4c and the gate bottom protection region 4b are each a region including SiC obtained by implantation of p-type impurity ions into the current spreading layer 3, for example. A connection part of p⁺-type for connecting the respective first buried regions 4a and 4c and the gate bottom protection region 4b together may be selectively provided on the front side or the back side in the sheet of FIG. 1.

Second buried regions 5a and 5b of the second conductivity-type (p-type) are provided on the top surface side of the first buried regions 4a and 4c at the upper part of the current spreading layer 3. The second buried regions 5a and 5b electrically connect the first buried regions 4a and 4c and the base regions 6a and 6b to each other. The bottom surfaces of the second buried regions 5a and 5b are in contact with the top surfaces of the first buried regions 4a and 4c. The side surfaces of the second buried regions 5a and 5b ate in contact with the current spreading layer 3 and the base regions 6a and 6b. The second buried regions 5a and 5b are each a region including SiC obtained by implantation of p-type impurity ions into the current spreading layer 3 and the base regions 6a and 6b, for example. The second buried regions 5a and 5b may have substantially the same impurity concentration as the first buried regions 4a and 4c, or may have either a lower impurity concentration or a higher impurity concentration than the first buried regions 4a and 4c. The impurity concentration of the second buried regions 5a and 5b is in a range of about 1×10¹⁷ cm⁻³ or greater and 1×10¹⁹ cm⁻³ or less, for example.

Base contact regions 8a and 8b of p⁺-type having a higher impurity concentration than the second buried regions 5a and 5b are deposited on the top surface side of the second buried regions 5a and 5b. The base contact regions 8a and 8b are each a region including SiC obtained by implantation of p-type impurity ions into the base regions 6a and 6b, for example. The base contact regions 8a and 8b have an impurity concentration in a range of about 5×10¹⁸ cm⁻³ or greater and 5×10²⁰ cm⁻³ or less, for example. The base contact regions 8a and 8b may include either 3C—SiC or 4H—SiC.

The bottom surface of the base contact region 8a is in contact with the top surface of the second buried region 5a, and the side surface of the base contact region 8a is in contact with the source expansion part 71a and the source contact part 72a of the source region 7a. The bottom surface of the base contact region 8b is in contact with the top surface of the second buried region 5b, and the side surface of the base contact region 8b is in contact with the source expansion part 71b and the source contact part 72b of the source region 7b. The respective bottom surfaces of the base contact regions 8a and 8b are located at substantially the same depth as the respective bottom surfaces of the source expansion parts 71a and 71b of the source regions 7a and 7b, but may be either shallower than or deeper than the respective bottom surfaces of the source expansion parts 71a and 71b of the source regions 7a and 7b. The respective top surfaces of the second buried regions 5a and 5b are not necessarily in contact with the respective bottom surfaces of the p⁺-type base contact regions 8a and 8b.

An interlayer insulating film 13 is deposited on the top surface side of the gate electrode 12. The interlayer insulating film 13 is a single-layer film, such as a borophosphosilicate glass film (a BPSG film), a phosphosilicate glass film (a PSG film), a non-doped silicon oxide film without containing phosphorus (P) or boron (B) which is referred to as a non-doped silicate glass (NSG) film, a borosilicate glass film (a BSG film), or a silicon nitride (Si₃N₄) film, or a stacked-layer film including the above films stacked on one another. The interlayer insulating film 13 is provided with contact holes 13a and 13b so as to expose the respective top surfaces of the source contact parts 72a and 72b and the base contact regions 8a and 8b.

A first main electrode (a source electrode) (14, 15) is provided to cover the interlayer insulating film 13 and the respective top surfaces of the source contact parts 72a and 72b and the base contact regions 8a and 8b exposed to the contact holes 13a and 13b of the interlayer insulating film 13. The source electrode (14, 15) includes a barrier metal layer 14 as a lower layer and a source wiring electrode 15 as an upper layer. The barrier metal layer 14 includes metal such as titanium nitride (TiN), titanium (Ti) or a stacked-layer structure of TiN/Ti including Ti as a lower layer, for example. The barrier metal layer 14 is directly in contact with the source contact parts 71a and 72b and the base contact regions 8a and 8b, and also in ohmic contact with the source contact parts 71a and 72b and the base contact regions 8a and 8b at a low resistance.

The source wiring electrode 15 is electrically connected to the respective source regions 7a and 7b and the respective base contact regions 8a and 8b via the barrier metal layer 14. The source wiring electrode 15 is provided separately from a gate wiring electrode (not illustrated) electrically connected to the gate electrode 12. The source wiring electrode 15 includes metal such as aluminum (Al), aluminum-silicon (Al—Si), aluminum-copper (Al—Cu), or copper (Cu), for example.

A second main region (a drain region) 1 of the first conductivity-type (n⁺-type) having a higher impurity concentration than the drift layer 2 is deposited on the bottom surface side of the drift layer 2. The drain region 1 is made of a semiconductor substrate (a SiC substrate) including 4H—SiC, for example. The drain region 1 has an impurity concentration in a range of about 1×10¹⁹ cm⁻³ or greater and 3×10²⁰ cm⁻³ or less, for example. The drain region 1 has a thickness in a range of about 30 micrometers or greater and 500 micrometers or smaller, for example. A dislocation conversion layer or a recombination promotion layer having a higher impurity concentration than the drift layer 2 and having a lower impurity concentration than the drain region 1 may be provided as an n-type buffer layer between the drift layer 2 and the drain region 1.

A second main electrode (a drain electrode) 16 is deposited on the bottom surface side of the drain region 1. The drain electrode 16 can be a single-layer film including gold (Au), or a metal film including titanium (Ti), nickel (Ni), and Au stacked in this order from the drain region 1 side, and may be further provided with a metal film including molybdenum (Mo) or tungsten (W), for example, as the lowermost layer. A drain contact layer such as nickel silicide (NiSiₓ) film for ohmic contact may be provided between the drain region 1 and the drain electrode 16.

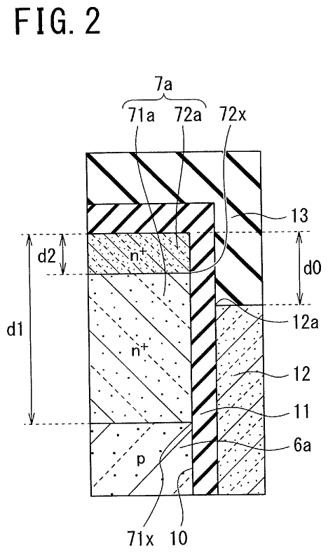

FIG. 2 is an enlarged cross-sectional view of region A including the source expansion part 71a and the source contact part 72a of the source region 7a, the gate insulating film 11, and the gate electrode 12 indicated by the broken line in FIG. 1. The configurations of the source expansion part 71a and the source contact part 72a and the positional relation between the source expansion part 71a and the source contact part 72a and the gate electrode 12 are described below with reference to FIG. 2.

The source expansion part 71a is a region having fewer crystal defects than the source contact part 72a while hardly taking over the crystal defects in the source contact part 72a. The source expansion part 71a mainly includes 4H—SiC (a 4C structure). The proportion of 4H—SiC included in the source expansion part 71a is in a range of about 90% or greater and 100% or smaller, for example. The source expansion part 71a may further have an amorphous structure and include a small amount of 3C—SiC other than 4H—SiC, for example.

A depth d1 from the top surface of the source contact part 72a to the bottom surface of the source expansion part 71a is in a range of about 200 nanometers or greater and 450 nanometers or smaller, for example. The source expansion part 71a has a thickness in a range of about 150 nanometers or greater and 400 nanometers or smaller, for example. The source expansion part 71a has a lower impurity concentration than the source contact part 72a. The impurity concentration of the source expansion part 71a is in a range of about 1×10¹⁶/cm⁻³ or greater and 1×10¹⁹/cm⁻³ or less, for example. The source expansion part 71a includes phosphorus (P) or nitrogen (N) as n-type impurity ions, for example. The source expansion part 71a may include arsenic (As) as n-type impurity ions.

The source contact part 72a is a region including 3C—SiC (a 3C structure). The proportion of 3C—SiC included in the source contact part 72a is in a range of about 10% or greater and 100% or smaller, for example. The source contact part 72a may have a mixed-crystal structure of 3C—SiC and 4H—SiC. The source contact part 72a may further have an amorphous structure and include 4H—SiC other than 3C—SiC, for example. The source contact part 72a including 3C—SiC, which has a narrower bandgap than 4H—SiC, can be led to be in ohmic contact with the source electrode (14, 15) at a low resistance. To achieve a good ohmic contact with the source electrode (14, 15), the proportion of 3C—SiC included in the source contact part 72a is preferably 10% or greater.

A depth d2 from the top surface to the bottom surface of the source contact part 72a (a thickness of the source contact part 72a) is in a range of about 30 nanometers or greater and 100 nanometers or smaller, for example. The source contact part 72a has a higher impurity concentration than the source expansion part 71a. The impurity concentration of the source contact part 72a is in a range of about 1×10¹⁹/cm⁻³ or greater and 1×10²²/cm⁻³ or less, for example. The source contact part 72a includes phosphorus (P) or arsenic (As) as n-type impurity ions, for example. The source contact part 72a may include nitrogen (N) as n-type impurity ions. The source contact part 72a may include P, As, and N combined as appropriate as n-type impurity ions.

The crystal structures of the source expansion part 71a and the source contact part 72a can be formed independently of each other such that some conditions such as the element to be implanted, the temperature during the ion implantation, the dose (the impurity concentration), and the activation temperature are changed for each of the source expansion part 71a and the source contact part 72a. The process of forming the source contact part 72a including 3C—SiC implants n-type impurity ions having a high impurity concentration to 4H—SiC at a room temperature so as to destroy 4H—SiC to form an amorphous structure by use of damage during the ion implantation. The execution of the following activation annealing leads the amorphous structure to turn to 3C—SiC when recrystallized, so as to form the source contact part 72a including 3C—SiC.

The process of forming the source expansion part 71a including 4H—SiC implants n-type impurity ions to 4H—SiC at a high temperature (for example, about at 500° C.) at an impurity concentration that can sufficiently avoid destruction of the structure of 4H—SiC, so as to keep 4H—SiC to form the source expansion part 71a.

The respective crystal structures of the source expansion part 71a and the source contact part 72a can be measured (observed) such that a ratio of the areas of the crystal structures on the surfaces is measured by use of a field-emission scanning electron microscope (FE-SEM) and electron backscatter diffraction (EBSD). The present embodiment executed the measurement, as an example, such that samples were prepared under the common conditions of the element of the impurity ions to be implanted, the dose (the impurity concentration), and the activation temperature, but the temperature upon the ion implantation was changed that was 500° C. and a room temperature (25° C.) so as to be measured by use of FE-SEM and EBSD. The proportion of 4H—SiC on the surface in the sample obtained at 500° C. was 100%. The proportion of 4H—SiC on the surface in the sample obtained at the room temperature was 86%, while the proportion of 3C—SiC was 14%.

As illustrated in FIG. 2, the top surface (the upper end) 12a at the position of the end part of the gate electrode 12 in contact with the gate insulating film 11 is located at a position deeper than the bottom surface (the lower end) 72x of the source contact part 72a in contact with the gate insulating film 11 and shallower than the bottom surface (the lower end) 71x of the source expansion part 71a in contact with the gate insulating film 11. The top surface 12a of the gate electrode 12 at the position in contact with the gate insulating film 11 may be the uppermost surface of the gate electrode 12. When the entire top surface of the gate electrode 12 is curved to be convex downward, for example, the middle of the top surface of the gate electrode 12 may be located at a position deeper than the top surface 12a of the end part of the gate electrode 12.

The gate electrode 12 and the source expansion part 71a are opposed to each other with the gate insulating film 11 interposed. The gate electrode 12 and the source contact part 72a are not opposed to each other with the gate insulating film 11 interposed. The source contact part 72a is opposed to the interlayer insulating film 13 with the gate insulating film 11 interposed. A drop amount d0 of the gate electrode 12 from the top surface of the source contact part 72a is in a range of about 100 nanometers or greater and 300 nanometers or smaller, for example. The drop amount d0 of the gate electrode 12 and the position of the top surface 12a of the gate electrode 12 in contact with the gate insulating film 11 can be regulated such that the etching conditions for the gate electrode 12 are adjusted, for example.

The source expansion part 71b and the source contact part 72b of the source region 7b illustrated in FIG. 1 have the configurations common to those of the source expansion part 71a and the source contact part 72a of the source region 7a, respectively, and overlapping explanations are not repeated below. The positional relation between the source expansion part 71b and the source contact part 72b of the source region 7b and the gate electrode 12 is common to that between the source expansion part 71a and the source contact part 72a of the source region 7a and the gate electrode 12, and overlapping explanations are not repeated below.

The SiC semiconductor device according to the first embodiment during the operation applies a positive voltage to the drain electrode 16 while using the source electrode (14, 15) as a ground potential, and causes an inversion layer (a channel) to be formed in the respective base regions 6a and 6b toward the side surfaces of the trench 10 so as to be in the ON-state when a positive voltage of a threshold or greater is applied to the gate electrode 12. In the ON-state, a current flows from the drain electrode 16 toward the source electrode (14, 15) through the drain region 1, the drift layer 2, the current spreading layer 3, the inversion layers of the base regions 6a and 6b, and the source regions 7a and 7b. When the voltage applied to the gate electrode 12 is smaller than the threshold, the SiC semiconductor device is led to be the OFF-state since no inversion channel is formed in the base region 6a or 6b, and no current flows from the drain electrode 16 toward the source electrode (14, 15).

The SiC semiconductor device according to the first embodiment, in which the source region 7a has the two-layer structure including the source expansion part 71a and the source contact part 72a, and the source expansion part 71a as an upper layer in contact with the source electrode (14, 15) includes 3C—SiC, can lead the source contact part 72a to be in ohmic contact with the source electrode (14, 15) at a low resistance without a provision of a silicide layer including nickel (Ni) silicide or the like. The present embodiment thus can avoid a problem of separation of such a silicide layer, as compared with a case of including the silicide layer.

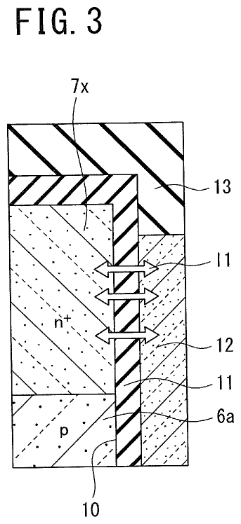

When it is assumed, as illustrated in FIG. 3, that a source region 7x including 3C—SiC and having a single-layer structure is opposed to the gate electrode 12 with the gate insulating film 11 interposed, the source region 7x including 3C—SiC could be in ohmic contact with the source electrode (14, 15). However, since 3C—SiC tends to have crystal defects and lead to a roughened surface more than 4H—SiC, a leak current 11 could flow between the gate electrode 12 and the source region 7x.

As compared with the conventional case described above, the SiC semiconductor device according to the first embodiment has the configuration in which the top surface 12a of the gate electrode 12 is located at a position deeper than the bottom surface 72x of the source contact part 72a and shallower than the bottom surface 71x of the source expansion part 71a. This configuration leads the source expansion part 71a of the source region 7a having fewer crystal defects to be opposed to the gate electrode 12 with the gate insulating film 11 interposed, while the source contact part 72a of the source region 7a having larger crystal defects is not opposed to the gate electrode 12 with the gate insulating film 11 interposed. The present embodiment thus can suppress a cause of a leak current flowing between the source region 7a and the gate electrode 12.

### <Method of Manufacturing Semiconductor Device>

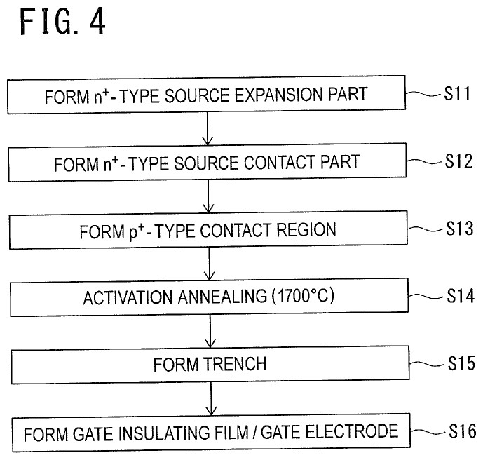

An example of a method of manufacturing the SiC semiconductor device according to the first embodiment is described below. It should be understood that the method of manufacturing the SiC semiconductor device described below is an example, and the SiC semiconductor device can be manufactured by other methods including modified examples of this embodiment within the scope of the appended claims. FIG. 4 is a flowchart showing a procedure of a part of the method of manufacturing the SiC semiconductor device according to the first embodiment. The following explanations are made with reference to FIG. 4 as necessary.

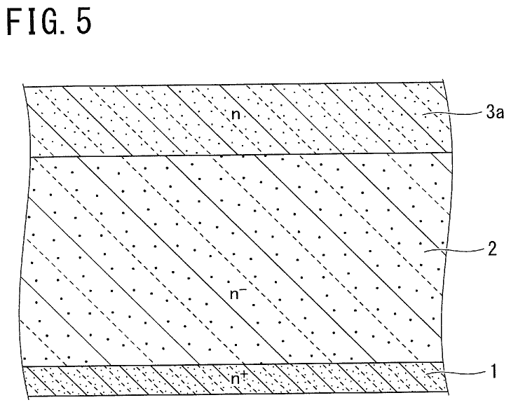

First, the semiconductor substrate (the SiC substrate) 1 (refer to FIG. 1) including 4H—SiC of n⁺-type doped with n-type impurity ions such as nitrogen (N) is prepared. The top surface of the SiC substrate has an off-angle of three to eight degrees with respect to a (0001) plane, for example. The drift layer 2 (refer to FIG. 1) including 4H—SiC of nt-type doped with n-type impurity ions such as N and having a lower impurity concentration than the SiC substrate 1 is then epitaxially grown on the top surface of the SiC substrate 1. Next, as illustrated in FIG. 5, an n-type layer 3a including 4H—SiC of n-type doped with n-type impurity ions such as N and having a higher impurity concentration than the drift layer 2 is epitaxially grown on the top surface of the drift layer 2. The n-type layer 3a may be formed by the implantation of n-type impurity ions such as nitrogen (N) into the upper part of the drift layer 2, instead.

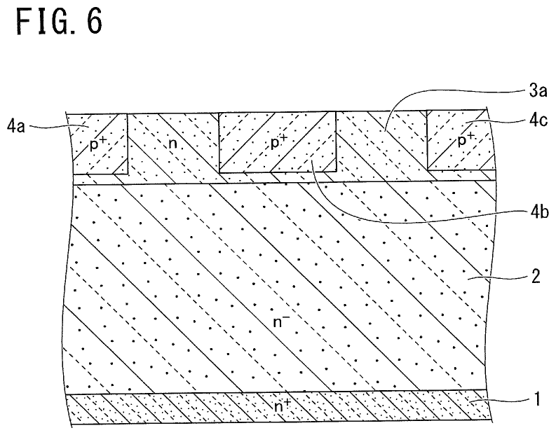

Next, an oxide film is deposited on the top surface of the n-type layer 3a by chemical vapor deposition (CVD), for example. A photoresist film is then applied to the top surface of the oxide film, and the oxide film is delineated by photolithography and dry etching, for example. Using the delineated oxide film as a mask for ion implantation, p-type impurity ions such as aluminum (Al) is selectively implanted. Instead of the oxide film, a photoresist film may be used as a mask for ion implantation. The oxide film used as the mask for ion implantation is then removed. This step selectively provides the p⁺-type first buried regions 4a and 4c and the p⁺-type gate bottom protection region 4b at the upper part of the n-type layer 3a, as illustrated in FIG. 6.

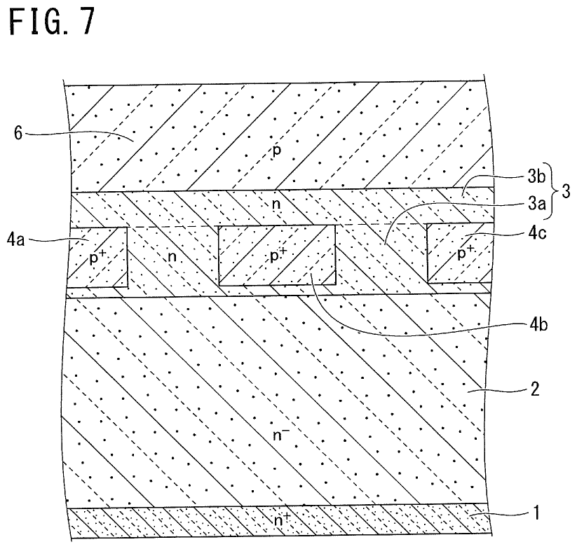

Next, an n-type layer 3b (refer to FIG. 7) including 4H—SiC of n-type is epitaxially grown on the respective top surfaces of the n-type layer 3a, the first buried regions 4a and 4c, and the gate bottom protection region 4b. This step provides the current spreading layer 3 including the n-type layer 3a and the n-type layer 3b. Next, as illustrated in FIG. 7, the base region 6 including 4H—SiC of p-type is epitaxially grown on the top surface of the current spreading layer 3.

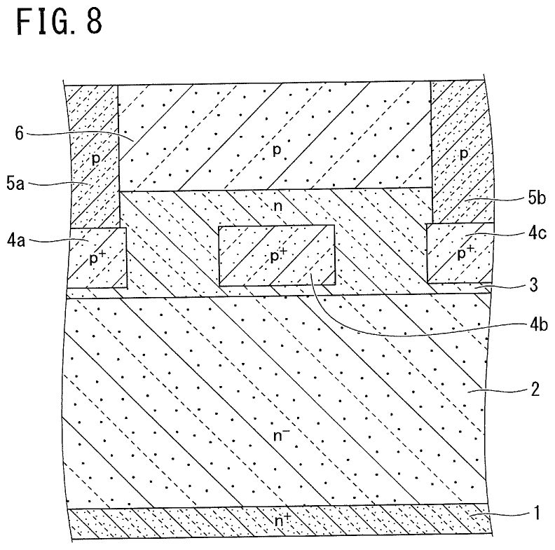

Next, an oxide film is deposited on the top surface of the base region 6 by CVD or the like. A photoresist film is then applied to the top surface of the oxide film, and the oxide film is delineated by photolithography and dry etching. Using the delineated oxide film as a mask for ion implantation, p-type impurity ions such as aluminum (Al) is selectively implanted. Instead of the oxide film, a photoresist film may be used as a mask for ion implantation. The oxide film used as the mask for ion implantation is then removed. This step selectively provides the p-type second buried regions 5a and 5b on the top surface side of the first buried regions 4a and 4c, as illustrated in FIG. 8.

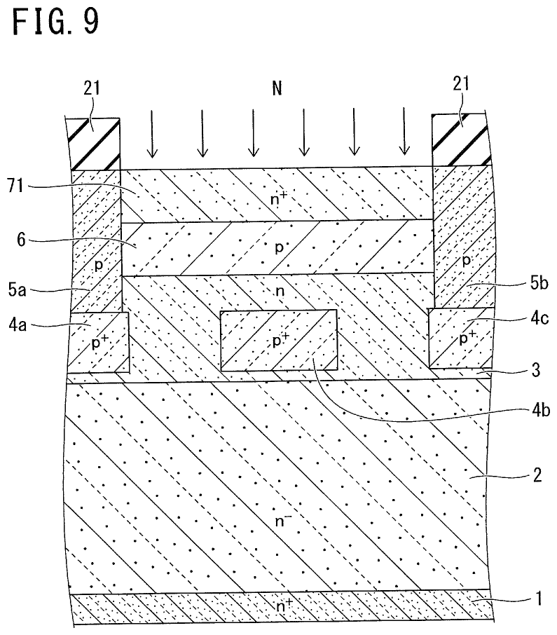

Next, a step of forming an n⁺-type source expansion part in step S11 shown in FIG. 4 is executed. The step of forming the n⁺-type source expansion part deposits an oxide film 21 (refer to FIG. 9) on the top surface of the base region 6 by CVD or the like. A photoresist film is then applied to the top surface of the oxide film 21, and the oxide film 21 is delineated by photolithography and dry etching. Using the delineated oxide film 21 as a mask for ion implantation, n-type impurity ions such as nitrogen (N) are implanted, as illustrated in FIG. 9. Instead of the oxide film 21, a photoresist film may be used as a mask for ion implantation. This step provides the n⁺-type source expansion part 71 at the upper part of the base region 6.

Upon the ion implantation for the source expansion part 71, the use of phosphorus (P: element number 15) having a relatively small atomic number as the n-type impurity ions is preferable, and the use of N (element number 7) having a smaller atomic number is more preferable in order to have less damage than the ion implantation for the source contact part 72 described below. Instead of P or N, arsenic (As: element number 33) having a relatively large atomic number may be implanted. The temperature during the ion implantation in this step is set to be higher than the temperature during the ion implantation for the source contact part 72 described below, and is in a range of 300° C. or higher and 600° C. or lower, for example. The dose of the impurity ions to be implanted is set such that the impurity concentration of the source expansion part 71 is in a range of about 1×10¹⁶/cm⁻³ or greater and 1×10¹⁹/cm⁻³ or less, for example.

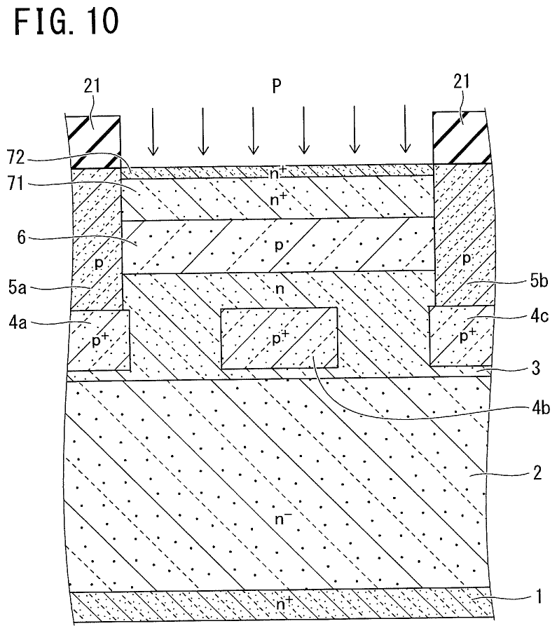

Next, a step of forming an n⁺-type source contact part in step S12 shown in FIG. 4 is executed. The step of forming the n⁺-type source contact part continuously uses the oxide film 21 as a mask for ion implantation, as illustrated in FIG. 10, so as to selectively implant n-type impurity ions such as phosphorus (P). Instead of the oxide film 21, a photoresist film may be used as a mask for ion implantation. This step provides the n⁺-type source contact part 72 on the top surface side of the source expansion part 71.

The execution of the ion implantation for the source contact part 72 breaks the structure of 4H—SiC on the top surface side of the source expansion part 71 so as to form the amorphous structure. To have greater damage than the ion implantation for the source expansion part 71 described above, the use of P (element number 15) having a relatively large atomic number as the n-type impurity ions is preferable, and the use of arsenic (As: element number 33) having a greater atomic number is more preferable.

Nitrogen (N) having a relatively small atomic number may be used instead. The same impurity ions may be implanted for the source contact part 72 as the impurity ions implanted for the source expansion part 71 described above, or different impurity ions may be implanted instead. The temperature during the ion implantation in this step is set to be lower than the temperature during the ion implantation for the source expansion part 71 described above, and is in a range of 20° C. or higher and 150° C. or lower, for example. The dose of the impurity ions to be implanted is set such that the impurity concentration of the source contact part 72 is set in a range of about 1×10¹⁹/cm⁻³ or greater and 1×10²²/cm⁻³ or less, for example, in total together with the impurity ions implanted into the source expansion part 71. The oxide film 21 used as the mask for ion implantation is then removed.

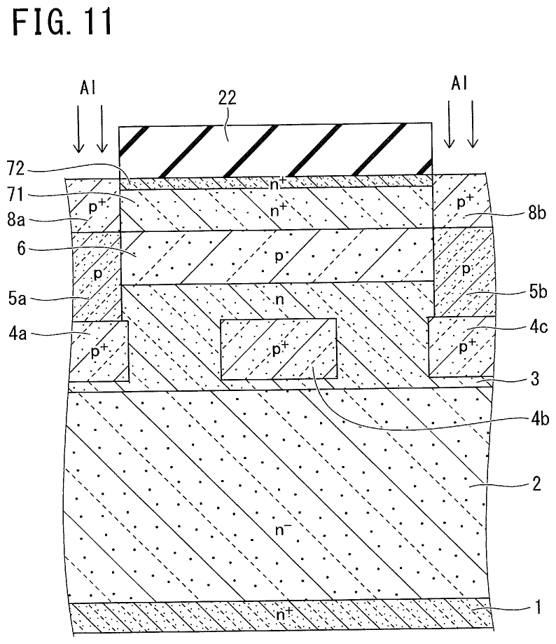

Next, a step of forming a p⁺-type contact region in step S13 shown in FIG. 4 is executed. The step of forming the p⁺-type contact region deposits an oxide film 22 on the top surface of the base region 6 by CVD or the like. A photoresist film is then applied to the top surface of the oxide film 22, and the oxide film 22 is delineated by photolithography and dry etching. Using the delineated oxide film 22 as a mask for ion implantation, p-type impurity ions such as aluminum (Al) or boron (B) are implanted, as illustrated in FIG. 11. Instead of the oxide film 22, a photoresist film may be used as a mask for ion implantation. This step selectively provides the p⁺-type base contact regions 8a and 8b on the top surface side of the second buried regions 5a and 5b. The oxide film 22 used as the mask for ion implantation is then removed.

Next, a step of activation annealing (annealing) in step S14 shown in FIG. 4 is executed. The activation annealing is executed at a temperature of about 1600° C. or higher and 1900° C. or lower, for example, so as to collectively activate the p-type impurity ions or the n-type impurity ions implanted into the first buried regions 4a and 4b, the gate bottom protection region 4b, the second buried regions 5a and 5b, the source expansion part 71, the source contact part 72, the base contact regions 8a and 8b, and the like. At this point, the amorphous structure in the source contact part 72 is recrystallized to turn to 3C—SiC, so as to form the source contact part 72 including 3C—SiC.

While the single activation annealing is collectively executed after all of the ion implantation steps, the activation annealing may be executed several times independently after each of the ion implantation steps. Alternatively, the present embodiment may include a step of forming a cap film including carbon (C), executing the activation annealing after the execution of the covering with the cap film, and then removing the cap film after the activation annealing.

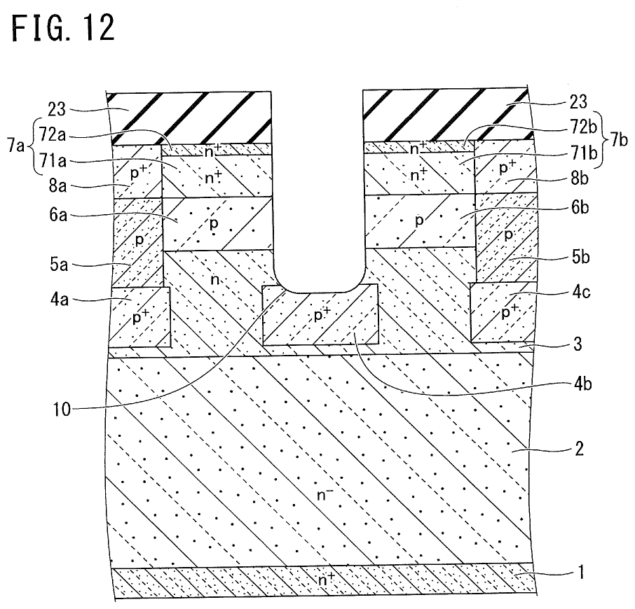

Next, a step of forming a trench in step S15 shown in FIG. 4 is executed. The step of forming the trench deposits an oxide film 23 (refer to FIG. 12) on the respective top surfaces of the base contact regions 8a and 8b and the source contact part 72 by CVD or the like. A photoresist film is then applied to the top surface of the oxide film 23, and the oxide film 23 is delineated by photolithography and dry etching. Using the delineated oxide film 23 as a mask for etching, the trenches 10 are selectively formed in the depth direction from the top surface of the source contact part 72 by etching such as reactive ion etching (RIE), as illustrated in FIG. 12. Instead of the oxide film 23, a photoresist film may be used as a mask for ion implantation.

The trench 10 penetrates the source expansion part 71, the source contact part 72, and the base region 6 so as to further dig down into the upper part of the current spreading layer 3 to reach the gate bottom protection region 4b. The provision of the trench 10 divides the source expansion part 71 into the respective source expansion parts 71a and 71b, divides the source contact part 72 into the respective source contact parts 72a and 72b, and divides the base region 6 into the respective base regions 6a and 6b. The source expansion parts 71a and 71b and the source contact parts 72a and 72b implement the respective source regions 7a and 7b. The oxide film 23 used as the mask for etching is then removed.

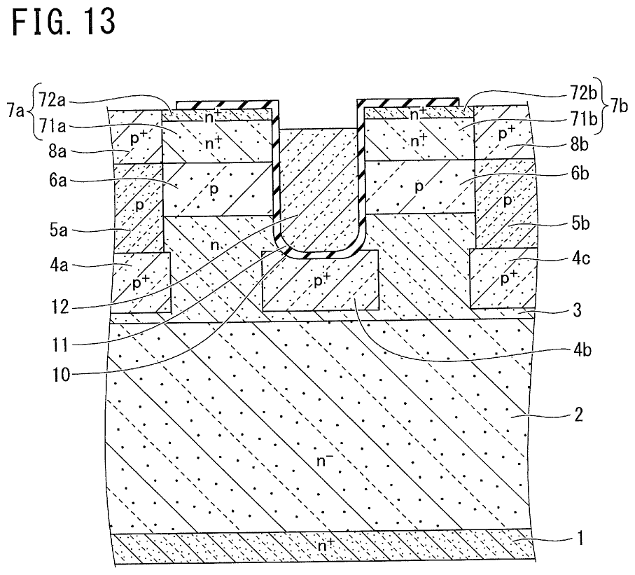

Next, a step of forming a gate insulating film/a gate electrode in step S16 shown in FIG. 4 is executed. The step of forming the gate insulating film/the gate electrode forms the gate insulating film 11 (refer to FIG. 13) on the bottom surface and the side surfaces of the trench 10 and the respective top surfaces of the source contact parts 72a and 72b and the base contact regions 8a and 8b by CVD, high temperature oxidation (HTO), or thermal oxidation, for example. Upon the formation of the gate insulating film 11, annealing (PDA: post deposition annealing) is executed at a temperature in a range of about 900° C. or higher and 1350° C. or lower, for example.

Next, a polysilicon layer (a doped polysilicon layer) heavily doped with impurity ions such as phosphorus (P) or boron (B) is deposited to fill the inside of the trench 10 by CVD or the like. Apart of the polysilicon layer and a part of the gate insulating film 11 are then selectively removed by photolithography and dry etching. This step provides the insulated gate electrode structure (11, 12) implemented by the gate insulating film 11 and the gate electrode 12, as illustrated in FIG. 13. The drop amount d0 of the gate electrode 12 is adjusted in this step such that the top surface 12a of the gate electrode 12 in contact with the gate insulating film 11 is located at a position deeper than the bottom surface (the lower end) 72x of the source contact part 72a and shallower than the bottom surface (the lower end) 71x of the source expansion part 71a, as illustrated in FIG. 2.

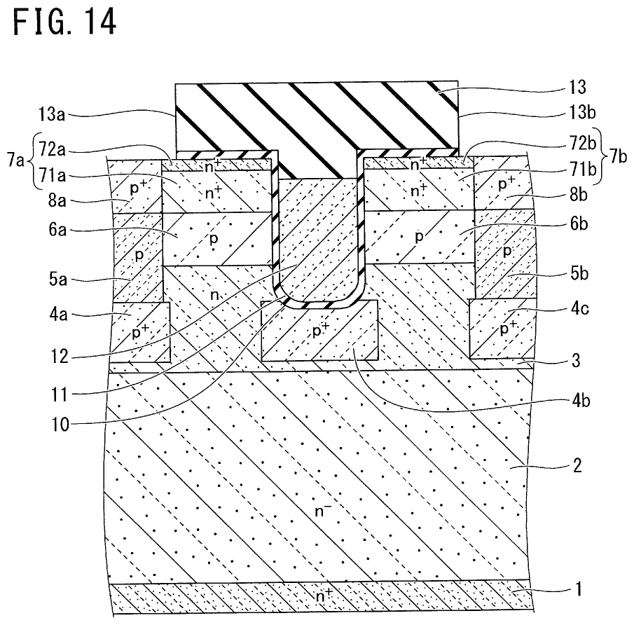

Next, the interlayer insulating film 13 (refer to FIG. 14) is deposited on the top surface of the insulated gate electrode structure (11, 12) by CVD or the like. A part of the interlayer insulating film 13 is then selectively removed by photolithography and dry etching so as to open the contact holes 13a and 13b in the interlayer insulating film 13 to which the respective top surfaces of the source contact parts 72a and 72b and the base contact regions 8a and 8b are exposed, as illustrated in FIG. 14. This step may be followed by heat treatment (reflowing) for flattening the interlayer insulating film 13.

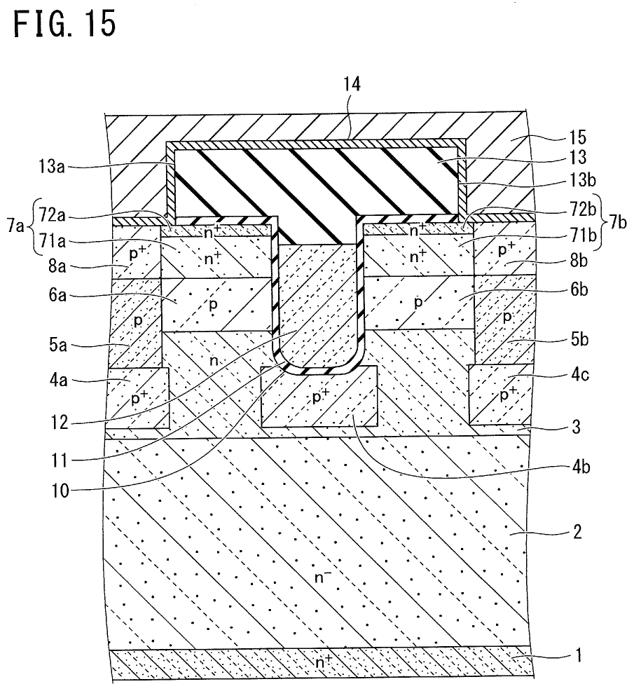

Next, the barrier metal layer 14 and the source wiring electrode 15 are sequentially formed to cover the top surface and the side surfaces of the interlayer insulating film 13 and the respective top surfaces of the source contact parts 72a and 72b and the base contact regions 8a and 8b so as to form the source electrode (14, 15) by sputtering or vapor deposition, for example, as illustrated in FIG. 15. The barrier metal layer 14 is to be in ohmic contact with the source contact parts 72a and 72b of the source regions 7a and 7b and the base contact regions 8a and 8b.

Next, the SiC substrate 1 is ground from the bottom surface side by grinding or chemical mechanical polishing (CMP) or the like to adjust the thickness so as to lead to the drain region 1. Thereafter, the drain electrode 16 (refer to FIG. 1) including gold (Au) is formed on the entire bottom surface of the drain region 1 by sputtering or vapor deposition, for example. The SiC semiconductor device illustrated in FIG. 1 is thus completed.

### Second Embodiment

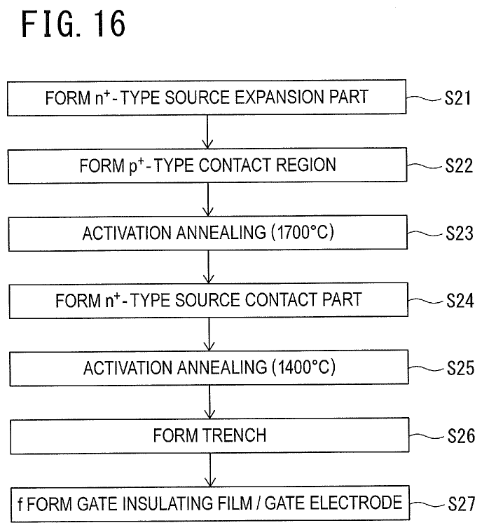

A SiC semiconductor device according to a second embodiment has a configuration similar to that of the SiC semiconductor device according to the first embodiment illustrated in FIG. 1. The method of manufacturing the SiC semiconductor device according to the second embodiment differs from the method of manufacturing the SiC semiconductor device according to the first embodiment in including a step of activation annealing for an ion implantation region other than the source contact part 72 in step S23 and a step of activation annealing for the source contact part 72 in step S25 executed independently of each other, as illustrated in FIG. 16.

The steps before a step of forming an n⁺-type source expansion part in step S21 shown in FIG. 16 are substantially the same as those in the method of manufacturing the SiC semiconductor device according to the first embodiment, and overlapping explanations are not repeated below. The step of forming the n⁺-type source expansion part in step S21 shown in FIG. 16 is the same as the step of forming the n⁺-type source expansion part in step S11 shown in FIG. 4, and forms the n⁺-type source expansion part 71 by the implantation of the n-type impurity ions, as illustrated in FIG. 9.

A step of forming a p⁺-type contact region in step S22 shown in FIG. 16 is the same as the step of forming the p⁺-type contact region in step S13 shown in FIG. 4, and forms the respective p⁺-type base contact regions 8a and 8b by the implantation of the p-type impurity ions, as illustrated in FIG. 11. The n⁺-type source contact part 72 at this point is not formed yet.

A step of activation annealing in step S23 shown in FIG. 16 is the same as the step of the activation annealing in step S14 shown in FIG. 4, and executes the activation annealing at a temperature of about 1600° C. or higher and 1900° C. or lower, for example, so as to collectively activate the p-type impurity ions or the n-type impurity ions implanted into the first buried regions 4a and 4c, the gate bottom protection region 4b, the second buried regions 5a and 5b, the source expansion part 71, the base contact regions 8a and 8b, and the like. The n⁺-type source contact part 72 at this point is not formed yet.

A step of forming an n⁺-type source contact part in step S24 shown in FIG. 16 is the same as the step of forming the n⁺-type source contact part in step S12 shown in FIG. 4, and forms the n⁺-type source contact part 72 by the implantation of the n-type impurity ions, as illustrated in FIG. 10. The damage caused by the ion implantation breaks 4H—SiC included in the source contact part 72 so as to provide the amorphous structure.

A step of activation annealing in step S25 shown in FIG. 16 executes the activation annealing at a temperature lower than that in the step of the activation annealing in step S23 shown in FIG. 16, which is in a range of about 1300° C. or higher and 1500° C. or lower, for example, so as to activate the n-type impurity ions implanted into the source contact part 72. This step recrystallizes the amorphous structure in the source contact part 72 to lead to 3C—SiC so as to form the source contact part 72 including 3C—SiC.

A step of forming a trench in step S26 shown in FIG. 16 is the same as the step of forming the trench in step S15 shown in FIG. 4, and selectively forms the trenches 10 from the top surface of the source contact part 72 in the depth direction by dry etching or the like, as illustrated in FIG. 12.

A step of forming a gate insulating film/a gate electrode in step S27 shown in FIG. 16 is the same as the step of forming the gate insulating film/the gate electrode in step S16 shown in FIG. 4, and buries the insulated gate electrode structure (11, 12) implemented by the gate insulating film 11 and the gate electrode 12 inside the trench 10, as illustrated in FIG. 13. The following steps after the step of forming the gate insulating film/the gate electrode in step S27 shown in FIG. 16 are substantially the same as those in the method of manufacturing the SiC semiconductor device according to the first embodiment, and overlapping explanations are not repeated below.

The method of manufacturing the SiC semiconductor device according to the second embodiment can lead the respective source regions 7a and 7b to be in ohmic contact with the source electrode (14, 15), and can also suppress a leak current flowing between the gate electrode 12 and the respective source regions 7a and 7b, so as to achieve the trench-gate SiC semiconductor device, as in the case of the method of manufacturing the SiC semiconductor device according to the first embodiment.

The method of manufacturing the SiC semiconductor device according to the second embodiment includes the step of the activation annealing for the ion implantation region other than the source contact part 72 in step S23 and the step of the activation annealing for the source contact part 72 in step S25 executed independently of each other. The crystal defect of 3C—SiC in the source contact part 72 is caused when the amorphous structure is recrystallized during the activation annealing, but the manufacturing method according to the second embodiment can reduce or avoid an expansion of the crystal defect from the source contact part 72 toward the source expansion part 71, since the step of the activation annealing in step S25 is executed at a lower temperature than in the step of the activation annealing in step S23.

### Third Embodiment

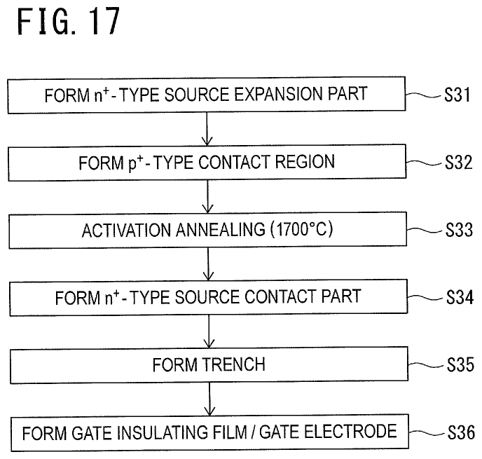

A SiC semiconductor device according to a third embodiment has a configuration similar to that of the SiC semiconductor device according to the first embodiment illustrated in FIG. 1. The method of manufacturing the SiC semiconductor device according to the third embodiment differs from the method of manufacturing the SiC semiconductor device according to the first embodiment in combining annealing (PDA) during a step of forming a gate insulating film/a gate electrode in step S36 shown in FIG. 17 with the step of the activation annealing for the source contact part 72.

The steps before a step of forming an n⁺-type source expansion part in step S31 shown in FIG. 17 are substantially the same as those in the method of manufacturing the SiC semiconductor device according to the first embodiment, and overlapping explanations are not repeated below. The step of forming the n⁺-type source expansion part in step S31 shown in FIG. 17 is the same as the step of forming the n⁺-type source expansion part in step S11 shown in FIG. 4, and forms the n⁺-type source expansion part 71 by the implantation of the n-type impurity ions, as illustrated in FIG. 9.

A step of forming a p⁺-type contact region in step S32 shown in FIG. 17 is the same as the step of forming the p⁺-type contact region in step S13 shown in FIG. 4, and forms the respective p⁺-type base contact regions 8a and 8b by the implantation of the p-type impurity ions, as illustrated in FIG. 11. The n⁺-type source contact part 72 at this point is not formed yet.

A step of activation annealing in step S33 shown in FIG. 17 is the same as the step of the activation annealing in step S14 shown in FIG. 4, and executes the activation annealing at a temperature of about 1600° C. or higher and 1900° C. or lower, for example, so as to collectively activate the p-type impurity ions or the n-type impurity ions implanted into the first buried regions 4a and 4rc, the gate bottom protection region 4b, the second buried regions 5a and 5b, the source expansion part 71, the base contact regions 8a and 8b, and the like. The n⁺-type source contact part 72 at this point is not formed yet.

A step of forming an n⁺-type source contact part in step S34 shown in FIG. 17 is the same as the step of forming the n⁺-type source contact part in step S12 shown in FIG. 4, and forms the n⁺-type source contact part 72 by the implantation of the n-type impurity ions, as illustrated in FIG. 10. The damage caused by the ion implantation breaks 4H—SiC included in the source contact part 72 so as to provide the amorphous structure.

A step of forming a trench in step S35 shown in FIG. 17 is the same as the step of forming the trench in step S15 shown in FIG. 4, and selectively forms the trenches 10 from the top surface of the source contact part 72 in the depth direction by dry etching or the like, as illustrated in FIG. 12.

A step of forming a gate insulating film/a gate electrode in step S36 shown in FIG. 17 is the same as the step of forming the gate insulating film/the gate electrode in step S16 shown in FIG. 4, and forms the gate insulating film 11 inside the trench 10, as illustrated in FIG. 13. A step of annealing is then executed during the formation of the gate insulating film 11 at a temperature lower than that in the step of the activation annealing in step S33 shown in FIG. 17, which is in a range of about 900° C. or higher and 1350° C. or lower, for example. This annealing activates the n-type impurity ions implanted into the source contact part 72. This step recrystallizes the amorphous structure in the source contact part 72 to lead to 3C—SiC so as to form the source contact part 72 including 3C—SiC. A step of burying the gate electrode 12 inside the trench 10 is then executed so as to form the insulated gate electrode structure (11, 12) implemented by the gate insulating film 11 and the gate electrode 12.

The following steps after the step of forming the gate insulating film/the gate electrode in step S36 shown in FIG. 17 are substantially the same as those in the method of manufacturing the SiC semiconductor device according to the first embodiment, and overlapping explanations are not repeated below.

The method of manufacturing the SiC semiconductor device according to the third embodiment can lead the respective source regions 7a and 7b to be in ohmic contact with the source electrode (14, 15), and can also suppress a leak current flowing between the gate electrode 12 and the respective source regions 7a and 7b, so as to achieve the trench-gate SiC semiconductor device, as in the case of the method of manufacturing the SiC semiconductor device according to the first embodiment.

While the crystal defect of 3C—SiC in the source contact part 72 is caused when the amorphous structure is recrystallized during the activation annealing, the method of manufacturing the SiC semiconductor device according to the third embodiment can reduce or avoid an expansion of the crystal defect from the source contact part 72 toward the source expansion part 71, since the annealing in the step of forming the gate insulating film/the gate electrode in step S36 is executed at a lower temperature than in the step of the activation annealing in step S33. Further, the manufacturing method according to the third embodiment combines the annealing during the step of forming the gate insulating film/the gate electrode in step S36 with the activation annealing for the source contact part 72, so as to avoid an increase in the number of the manufacturing steps.

### OTHER EMBODIMENTS

As described above, the invention has been described according to the first to third embodiments, but it should not be understood that the description and drawings implementing a portion of this disclosure limit the invention. Various alternative embodiments of the present invention, examples, and operational techniques will be apparent to those skilled in the art from this disclosure.

For example, while the first to third embodiments have been illustrated above with the case of using the MOSFET as the semiconductor device, the present invention can also be applied to an insulated gate bipolar transistor (IGBT) having a structure provided with a p⁺-type collector region, instead of the n⁺-type drain region 1. The present invention can further be applied to a reverse-conducting insulated gate bipolar transistor (RC-IGBT) or a reverse-blocking insulated gate bipolar transistor (RB-IGBT), instead of the simple IGBT.

Further, the configurations disclosed in the first to third embodiments may be combined as appropriate within a range that does not contradict with the scope of the respective embodiments. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present specification.

What is claimed is:

1. A silicon carbide semiconductor device comprising:
a drift layer of a first conductivity-type including silicon carbide;
a base region of a second conductivity-type including silicon carbide provided on a top surface side of the drift layer;
a main region of the first conductivity-type including silicon carbide provided on a top surface side of the base region;
a gate insulating film provided inside a trench penetrating the main region and the base region;
a gate electrode buried inside the trench with the gate insulating film interposed; and
a main electrode provided in contact with the main region,
wherein the main region includes
a source expansion part with a bottom surface in contact with the base region, and
a source contact part having a 3C structure provided on a top surface side of the source expansion part so as to be in contact with the main electrode, and
a top surface of the gate electrode at a position in contact with the gate insulating film is deeper than a bottom surface of the source contact part and is shallower than a bottom surface of the source expansion part.

2. The silicon carbide semiconductor device of claim 1, wherein a proportion of the 3C structure included in the source contact part is in a range of 10% or higher and 100% or smaller.

3. The silicon carbide semiconductor device of claim 1, wherein the source contact part includes phosphorus or arsenic as an impurity.

4. The silicon carbide semiconductor device of claim 1, wherein the source contact part has an impurity concentration in a range of 1×10¹⁹/cm⁻³ or greater and 1×10²²/cm⁻³ or less.

5. The silicon carbide semiconductor device of claim 1, wherein the source contact part has a thickness in a range of 30 nanometers or greater and 100 nanometers or smaller.

6. The silicon carbide semiconductor device of claim 1, wherein the source expansion part includes nitrogen or phosphorus as an impurity.

7. The silicon carbide semiconductor device of claim 1, wherein the source expansion part has an impurity concentration in a range of 1×10¹⁶/cm⁻³ or greater and 1×10¹⁹/cm⁻³ or less.

8. The silicon carbide semiconductor device of claim 1, wherein the source expansion part has a thickness in a range of 150 nanometers or greater and 400 nanometers or smaller.

9. The silicon carbide semiconductor device of claim 1, wherein a drop amount of the gate electrode from a top surface of the source contact part to the top surface of the gate electrode is in a range of 100 nanometers or greater and 300 nanometers or smaller.
